(19) United States
(12) Patent Application Publication
(10) Pub. No.: US 2009/0315631 A1
(43) Pub. Date: Dec. 24, 2009

(54) Methods and Apparatus Utilizing Quantum Inductance of Nanoscale Structures

(75) Inventors: Donhee Ham, Cambridge, MA (US); Xiaofeng Li, Henan (CN)

Correspondence Address: WOLF GREENFIELD & SACKS, P.C., 600 ATLANTIC AVENUE, BOSTON, MA, 02210-2206, US

(73) Assignee: President and Fellows of Harvard College, Cambridge, MA (US)

(21) Appl. No.: 12/083,747

(22) PCT Filed: Oct. 30, 2006
(86) PCT No.: PCT/US2006/042295

§ 371 Date: Sep. 11, 2009

Related U.S. Application Data
(60) Provisional application No. 60/730,836, filed on Oct. 28, 2005.

(51) Int. Cl. H03B 5/18

(52) U.S. Cl. 331/117 FE

(57) ABSTRACT

Methods and apparatus utilizing the quantum inductance of one-dimensional (ID) nanoscale structures (e.g., nanowires, carbon nanotubes). In one exemplary circuit implementation, all elements of a high-frequency circuit path are constituted by nanoscale structures without significant intervening structures (e.g., metal contacts) that would introduce undesirable resistance in the high-frequency circuit path. In this manner, the deleterious effects of contact resistance (e.g., metal-to-nanostructure interfaces) on the quality factor associated with the quantum inductance, and ultimately operation of the circuit, may be significantly reduced or avoided.

### PRIORITY

The present disclosure claims a priority benefit to U.S. Provisional Application Ser. No. 60/730,836, filed Oct. 28, 2005, entitled “Method and Apparatus for Integrated Circuits Utilizing Quantum Inductance of 1-dimensional Nanoscale Devices,” which application is hereby incorporated herein by reference.

### GOVERNMENT SPONSORED RESEARCH

Some of the research relating to the subject matter disclosed herein was sponsored by the AFOSR Nanotechnology Initiative of the United States Air Force, award no. FA 950-06-1-0305, and the United States government may have certain rights to some disclosed subject matter.

### BACKGROUND

Inductors constitute essential components in most integrated circuits employed in radio frequency (RF) applications, such as oscillators, amplifiers, filters, delay elements, and matching networks. For some applications, using conventional integrated circuit fabrication techniques (e.g., CMOS processing technology), a magnetic inductor may be implemented as a coiled conducting path having a number of coil turns (e.g., an aluminum or copper path having a path width on the order of approximately 10 micrometers to 30 micrometers) fabricated on a semiconductor (e.g., Si) substrate. FIG. 1 illustrates one example of such an inductor 102 disposed on a portion of a semiconductor substrate 104. Although FIG. 1 illustrates a generally hexagonal shape for the inductor 102, inductors having other shapes (e.g., essentially square) may be fabricated.

The magnetic inductance associated with inductors similar to that shown in FIG. 1 is approximately on the order of 1 pico-Henry per micrometer length of the coiled conducting path (i.e., 1 pH/μm). Accordingly, the overall dimensions and number of turns of the inductor 102 generally is dictated by a desired inductance suitable for a particular circuit application. For purposes of illustration, to achieve a magnetic inductance Lₘ on the order of 2.5 nano-Henries (nH) for the inductor 102, the coiled conducting path of the inductor needs to have a total length on the order of 2500 micrometers; in one exemplary implementation based on CMOS processing technology, this results in an overall “footprint” of the inductor on the order of 200 micrometers by 200 micrometers, with approximately three to four coil turns (one exemplary dimension of the outermost coil turn of the inductor 102 is indicated in FIG. 1 with the reference numeral 106).

An important frequency-related attribute of a magnetic inductor for use in a variety of RF circuits is given by a “quality factor” Q. The quality factor Q of a frequency dependent system generally is defined as a ratio of a peak or resonant frequency of the system to the frequency bandwidth of the system (i.e., the frequency range between the half-power points of the overall frequency response of the system). The quality factor Q alternatively may be viewed as a ratio of the maximum energy stored in the system to the total energy lost by the system in a given time period. In view of the foregoing, systems with a relatively large Q generally are viewed as being “frequency selective,” in that they support frequencies close to a given resonant frequency with relatively little energy loss. In contrast, systems with a relatively smaller Q do not necessarily have a significant frequency preference and are often viewed as somewhat lossy systems.

With respect to inductors, the magnetic inductor discussed above has a winding resistance from the metal wire forming the coils. A typical winding resistance for the conductor employed in the magnetic inductor 102 shown in FIG. 1 is on the order of 1.0 to 1.5 ohm/nH. The inductor's winding resistance converts electrical current flowing through the coils into heat, thus-causing a loss of “inductive quality.” The quality factor Q of a magnetic inductor is given by the ratio of its inductive reactance (magnetic inductance Lₘ) to its winding resistance R at a given frequency ω=2πf, i.e.,

$$Q = \frac{ω {L}_{m}}{R} , \qquad ( 1 )$$

and is a measure of the inductor's efficiency at the given frequency ω (relatively higher values of Q indicate a more efficient inductor at the given frequency). To provide an illustrative example, a magnetic inductor similar to that discussed above in connection with FIG. 1, having a magnetic inductance of approximately 2.5 nH and a winding resistance of approximately 3 ohms, has a quality factor Q of approximately five (5) at a frequency of f=955 MHz (corresponding to a radian frequency ω of approximately 6×10⁹ rad/sec), which is acceptable for many RF circuit applications.

“Nanowires” generally are defined as structures that have a lateral size (e.g., diameter) on the order of tens of nanometers or less. At these scales, quantum mechanical effects are significant—hence such wires also are commonly known as “quantum wires.” Various types of nanowires exist including, but not limited to, metallic (e.g., Ni, Pt, Au), semiconducting (e.g., InP, Si, GaN, etc.), and insulating (e.g., SiO₂, TiO₂). An important class of nanowires includes “carbon nanotubes,” discussed further below.

Nanowires typically exhibit aspect ratios (the ratio between length to width) of 1000 or more. As such they are often referred to as one-dimensional (1D) materials. Nanowires have many interesting properties that are not seen in bulk (three dimensional) materials, as electrons in nanowires are confined laterally and thus occupy energy levels that are different from the traditional continuum of energy levels or bands found in bulk materials.

Nanowires find application in electronics and electrical circuits. For example, both p-type and n-type semiconductors may be formed using chemically-doped semiconductor nanowires to create p-n junctions, p-type and n-type active components (e.g., transistors), and ultimately logic gates.

Carbon nanotubes (CNTs) are a class of nanowire that provide another example of a nanoscale structure (or “nanostructure”). CNTs have a cylindrical form composed of carbon molecules, wherein the diameter of a CNT generally is on the order of a few nanometers. These structures have a number of noteworthy material properties that implicate a variety of useful applications, including applications in the electrical arts.

CNTs are categorized as either single-walled nanotubes (SWNTs) or multi-walled nanotubes (MWNTs). Most single-walled nanotubes (SWNT) have a diameter of close to one nanometer, with a tube length that can be many thousands of times larger. CNTs are composed of “graphene,” which is the name given to a single layer of carbon atoms densely packed into a benzene ring (i.e., honeycomb lattice) structure. A SWNT can be conceptualized by wrapping a one-atom-thick layer or sheet of graphene into a seamless cylinder. The manner in which the graphene sheet is wrapped is represented by a pair of indices (n,m) commonly referred to as a “chiral vector,” wherein the integers n and m denote the number of unit vectors along two directions in the honeycomb lattice of graphene.

SWNTs exhibit significant electrical properties that are not shared by the multi-walled carbon nanotube (MWNT) variants. Because of the symmetry and unique electronic structure of graphene, the structure and corresponding chiral vector of an SWNT strongly affects its electrical properties. For example, for a given chiral vector (n, m), if 2n+m=3q (where q is an integer), then the SWNT is considered metallic; otherwise the SWNT is considered as a semiconductor. In theory, metallic nanotubes can have an electrical current density more than 1,000 times greater than metals such as silver and copper. Because SWNTs can be excellent conductors, like other types of nanowires they find ready application in electronics and circuit miniaturization efforts. One exemplary application of SWNTs is in the development of field effect transistors (FETs) and logic gates employing both p-type and n-type FETs implemented in a single SWNT.

The conduction mechanicsm in CNTs is commonly described as “ballistic transport,” which refers to the transport of electrons in a medium where the electrical resistivity due to scattering of electrons by atoms, molecules or impurities in the medium itself is negligible or absent. For a given conducting medium, a moving electron has a “mean free path,” which is the average length that the electron can travel freely before colliding with atoms, molecules or impurities and subsequently deviating from its original path. Ballistic transport is observed when the mean free path of the electron is significantly bigger than the size of the medium through which the electron travels, such that the electron alters its motion primarily by hitting against the boundaries of the medium. By virtue of the significantly small diameter of CNTs (on the order of nanometers), there are simply fewer possible obstructions for moving electrons, other than the boundaries of the CNT itself; hence, ballistic transport is observed.

More specifically, ballistic transport in CNTs arises from primarily two conditions. First, since the carbon atoms of the graphene sheet from a perfect cylinder in a CNT, there are no dangling bonds at the surface (i.e., no unpaired electrons). Accordingly, scattering due to “surface traps” formed by dangling bonds is significantly reduced (as compared, for example, to the conduction channel formed at a Si/SiO₂ interface in a MOSFET). This behavior also applies to some other nanowires, such as nanowires having a silicon-germanium (Si/Ge) core structure (see Wei Lu et al., “One-dimensional Hole Gas in Germainum/Silicon Nanowire Heterostructures,” Proceedings of the National Academy of Sciences of the United States of America, Vol. 102, No. 29, July 2005, pp. 10046-10051, hereby incorporated by reference herein). Second, when electrons are scattered by acoustic phonons (the motion of the conductor's lattice), energy and momentum must be conserved. In the case of a one-dimensional structure, electrons can only move in forward or backward directions. Accordingly, it is more difficult to satisfy energy and momentum conservation when electrons are back-scattered in one dimension (as compared to two- or three-dimensional conductors, in which electrons can be scattered in all directions, making it easier to satisfy energy and momentum conservation). As a result, reduced scattering due to limited dimension generally applies to all 1D conductors.

Various research efforts represented in the relevant literature have endeavored to provide an appropriate circuit model for the effective electrical properties (DC to giga-Hertz or tera-Hertz) of one-dimensional (1D) nanostructures. For example, in one study, an effective circuit model based on a transmission line was proposed for metallic single-walled carbon nanotubes (SWNTs), and generally applicable as well for semiconducting carbon nanotubes, multi-walled carbon nanotubes, quantum wires in GaAs heterostructures, and other systems involving 1D interacting electrons (P. J. Burke, “Lüttinger Liquid Theory as a Model of the Gigahertz Electrical Properties of Carbon Nanotubes,” IEEE Transactions on Nanotechnology, Vol. 1, No. 3, September 2002, pp. 129-144, hereby incorporated herein by reference, and hereafter referred to as “the Burke study”).

In the Burke study referenced immediately above, expressions for a distributed electrostatic capacitance and distributed magnetic inductance (“classical” parameters), as well as a distributed quantum capacitance and a distributed quantum inductance due more specifically to the 1D nanostructures (“quantum” parameters), were derived for a SWNT. The distributed classical and quantum inductances and capacitances per unit length form a transmission line. The Burke study noted that, whereas the electrostatic and quantum capacitances respectively are of similar magnitudes (e.g., on the order of 50 to 100 atto-Farads/micrometer), the quantum inductance, also referred to as “kinetic inductance,” significantly dominates the magnetic inductance of the SWNT.

More specifically, as discussed above, in 1D nanoscale devices such as carbon nanotubes and nanowires, electrons travel ballistically over a distance on the order of one micrometer, due to the substantially reduced scattering and correspondingly increased mean free path in the 1D electron transport process. This microscopic picture of the ballistic electron transport translates into a macroscopic current-voltage relation, V=L dI/dt, where V and I are the voltage across, and the current through, the 1D nanoscale device, respectively, while L is the inductance. In 1D devices, it was found that the quantum inductance L_{q} arising from ballistic electron transport significantly dominates magnetic inductance Lₘ, such that the overall value for L in the above voltage-current relation is constituted primarily by L_{q} in the nanoscale device. However, as far as the voltage-current relation is concerned at the phenomenological level, there is essentially no difference between the 1D nanoscale device and a coiled metallic wire or path shown in FIG. 1 (giving rise to a purely magnetic inductance Lₘ), in that both function as an inductive element.

In the Burke study, calculations of the quantum inductance L_{q} were derived from calculations of the kinetic energy per unit length based on net current in the SWNT, from which the quantum inductance L_{q} may be derived based on the energy relationship (½)LI². In this manner, an exemplary quantum inductance L_{q} for the SWNT was found to be approximately 4 nH/μm (based on two conduction channels in a given SWNT, and an electron spin degeneration of two). In other types of nanowires having widths on the order of a few nanometers, a similar kinetic inductance theoretically is predicted. As compared to a magnetic inductance of approximately 1 pH/μm for the magnetic inductor 102 discussed above in connection with FIG. 1, the quantum inductance of the SWNT is on the order of 10³ to 10⁴ times larger than the magnetic inductance.

### SUMMARY

Based on the foregoing Applicants have recognized and appreciated that employing the quantum inductance that is characteristic of nanoscale structures such as nanowires, including carbon nanotubes (e.g., SWNTs), may provide for substantial miniaturization of RF circuits in which inductors are essential elements. Accordingly, various embodiments of the present disclosure are directed to methods and apparatus that utilize the quantum inductance of nanoscale structures.

Applicants also have recognized and appreciated that the quality factor Q of an inductor based on the quantum inductance of a nanoscale structure may be significantly compromised by a contact resistance arising from a coupling of the nanoscale structure to other circuit elements. For example, first consider the quality factor Q of a “nanoscale inductor” constituted by a CNT (e.g., SWNT or other nanowire. A resistance of the nanoscale inductor arises from scattering of electrons traveling through the SWNT; as discussed above, notwithstanding ballistic transport of electrons, some electron scattering due to acoustic phonons occurs. In particular, it is estimated that the mean free path l_{ac} of electrons in a SWNT, taking into account acoustic phonon scattering at room temperature (approximately 300 degrees Kelvin), is approximately 1.6 micrometers. The resistance R_{ac} resulting from acoustic phonon scattering is given approximately by:

$${R}_{ac} \approx 6.5 k Ω \cdot \frac{l}{{l}_{ac}} ,$$

where l is the actual length of the SWNT. Accordingly, at room temperature, a one micrometer long SWNT would have a resistance of approximately four (4) kΩ. Based on Eq. (1) above, at a frequency of approximately 1 GHz, this one micrometer long SWNT having a quantum inductance of 4 nH (L_{q}=4 nwH/m) and an associated contact resistance of 4 kΩ has a quality factor Q of only approximately 0.006.

In the foregoing example, it should be appreciated that the mean free path l_{ac} depends not only on the type and quality of the nanowire material, but on temperature as well. In particular, if the temperature is lowered to 30 degrees Kelvin, the mean free path l_{ac} increases by about a factor of 10 (which in turn has the effect of lowering the resistance R_{ac}). Accordingly, a higher quality factor for the nanoscale inductor may be realized at lower temperatures.

Now consider employing a nanoscale inductor constituted by a SWNT or other nanowire, together with other components of a conventionally fabricated integrated circuit; this would necessitate metal-to-nanostructure interfaces/contacts to connect the nanoscale inductor to the other circuit components. Such metal contacts typically have a considerable resistance associated with them (e.g., on the order of approximately 6.5 kΩ total for two contacts, one on each end of a nanostructure), and any appreciable contact resistance would appear in series with the inductor's resistance R_{ac}, thereby lowering the quality factor Q of the inductor.

Accordingly, an appreciable contact resistance due to a metal-nanostructure interface can undermine the benefits of increased quantum inductance of the nanostructure as compared to the magnetic inductance of conventional wire inductors. For example, with reference again to Eq. (1) above, at a frequency of approximately 1 GHz, the quality factor Q at room temperature of the one micrometer long SWNT with the added contact resistance of 6.5 kΩ in series with an R_{ac} of 4 kΩ decreases to 0.002. This is a notably low quality factor as compared to a quality factor of five (5) for the magnetic inductor 102 shown in FIG. 1 at approximately the same frequency (955 MHz). Even at a relatively higher frequency of 100 GHz, a one micrometer long SWNT has a room temperature quality factor of only approximately 0.2 (spiral inductors such as the inductor 102 of FIG. 1 generally do not function at frequencies beyond approximately 10 GHz, as the distributed capacitance of such inductors at these frequencies significantly degrades the quality factor).

In view of the foregoing, some embodiments of the present disclosure are directed to high-frequency circuits that utilize the quantum inductance of nanoscale structures while at the same time significantly reducing (and in some cases avoiding) the deleterious effects of contact resistance on circuit operation. In particular, one embodiment is directed to circuits in which all elements of a high-frequency circuit path are constituted by nanoscale structures without significant intervening structures (e.g., metal contacts) that would introduce undesirable resistance in the high-frequency circuit path.

In sum, one embodiment of the present disclosure is directed to an integrated circuit, comprising, a closed loop path formed by at least one nanoscale structure, and a pair of cross-coupled field effect transistors (FETs) implemented along the closed loop path, wherein two portions of the at least one nanoscale structure form respective channels of the cross-coupled FETs.

Another embodiment of the present disclosure is directed to a method, comprising: generating a standing wave on a closed loop path formed by at least one nanoscale structure.

Another embodiment of the present disclosure is directed to an apparatus, comprising a high-frequency current path formed by at least one nanoscale structure, and at least one non-nanoscale conducting structure coupled to the at least one nanoscale structure, wherein the high-frequency current path includes only the at least one nanoscale structure.

Another embodiment of the present disclosure is directed to a high-frequency integrated circuit oscillator comprising a closed loop path formed by at least one nanoscale structure and configured to generate a standing wave on the closed loop path.

It should be appreciated that all combinations of the foregoing concepts and additional concepts discussed in greater detail below are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

FIG. 1 is a diagram illustrating a conventional magnetic inductor fabricated according to a CMOS processing technique.

FIG. 2 is a circuit drawing of a conventional generic LC oscillator 108 employing cross-coupled field-effect transistors (FET).

FIG. 3 is a circuit drawing of the LC oscillator of FIG. 2 implemented using nanoscale structures, according to one embodiment of the present disclosure.

FIG. 4 shows an example of a carbon nanotube FET that may serve as a building block for components of the oscillator shown in FIG. 3.

FIG. 5 shows another example of a carbon nanotube FET that may serve as a building block for components of the oscillator shown in FIG. 3.

### DETAILED DESCRIPTION

Following below are more detailed descriptions of various concepts related to, and embodiments of, methods and apparatus according to the present disclosure for utilizing the quantum inductance of nanoscale structures. It should be appreciated that various aspects of the subject matter introduced above and discussed in greater detail below may be implemented in any of numerous ways, as the subject matter is not limited to any particular manner of implementation. Examples of specific implementations and applications are provided primarily for illustrative purposes.

Exemplary embodiments of the present disclosure are directed to high-frequency circuits that utilize the quantum inductance of nanoscale structures while at the same time significantly reducing (and in some cases avoiding) the deleterious effects of contact resistance on circuit operation. In particular, one embodiment is directed to circuits in which all elements of a high-frequency circuit path are constituted by nanoscale structures without significant intervening structures (e.g., metal contacts) that would introduce undesirable resistance in the high-frequency circuit path.

While it is envisioned that many types of circuit implementations requiring inductors may be realized according to the concepts disclosed herein, a specific example of an oscillator is discussed below to illustrate various aspects of the present disclosure. An oscillator constitutes one of the most basic and ubiquitous building blocks of communications systems, as well as a host of other applications. Essentially all communications systems at some point need a reference oscillator to facilitate a variety of communication-related functions. As a result, oscillator design in the high frequency regime is an active area of interest. Other circuit implementations that may utilize the quantum inductance of nanoscale structures according to the principles discussed herein include, but are not limited to, filters, amplifiers, delay elements, matching networks, and oscillator configurations other than those specifically discussed herein (e.g., Colpitts, Harley, inductor-gate-degenerated oscillators).

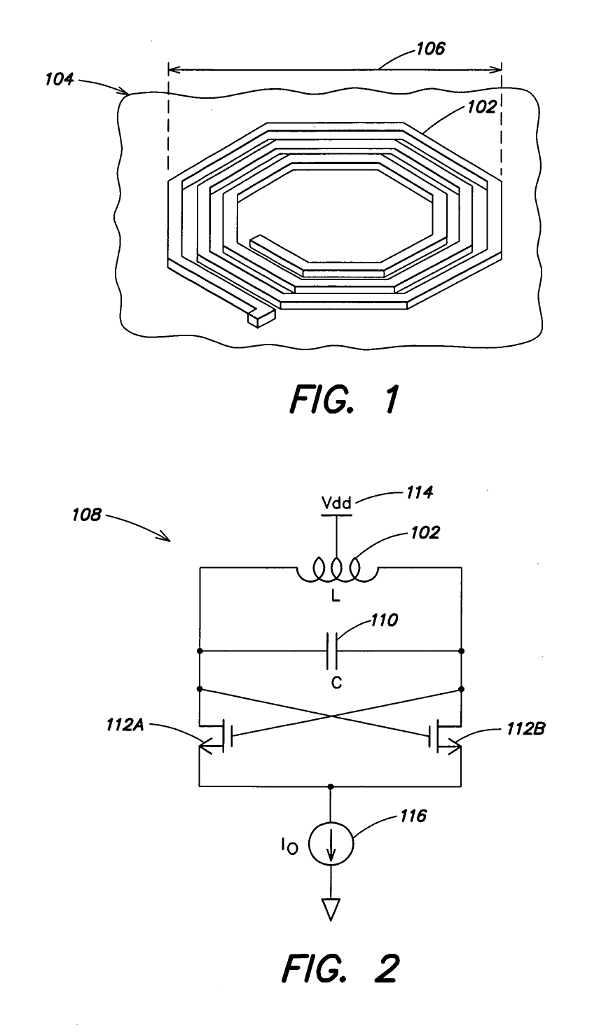

FIG. 2 is a circuit drawing of a conventional generic LC oscillator 108 employing cross-coupled field-effect transistors (FET). The LC oscillator 108 may be fabricated, for example, as an integrated circuit using conventional CMOS processing techniques. The basic components of the oscillator 108 include a magnetic inductor 102 similar to that shown in FIG. 1, a capacitor 110, and a pair of FETs 112A and 112B. A DC bias for the FETs 112A and 112B is provided by a DC voltage 114 (V_{dd}) and a MOS current source 116. The oscillating signal may be observed (i.e., taken as an output of the circuit) across the capacitor 110 (i.e., across the respective drains or gates of the FETs 112A and 112B).

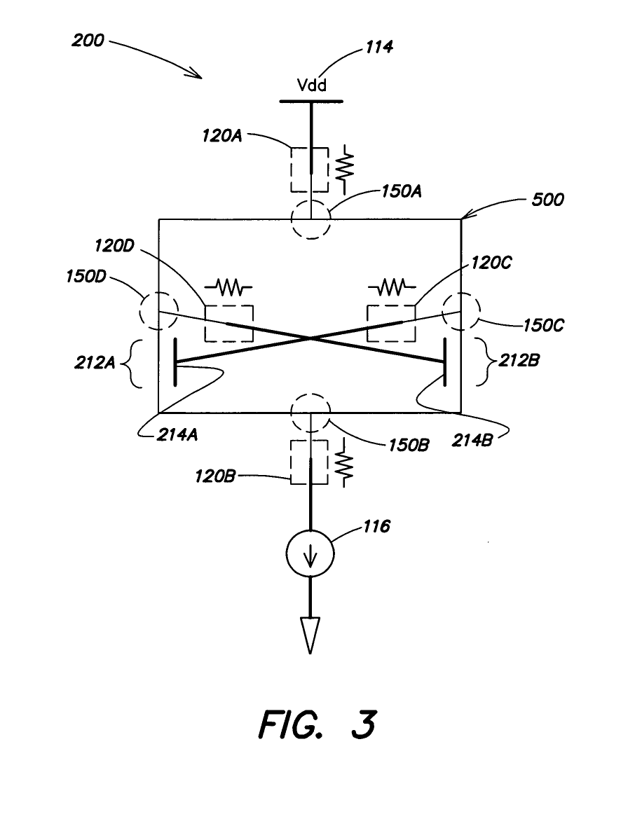

According to one embodiment of the present disclosure, the oscillator of FIG. 2 alternatively may be implemented using nanoscale structures. For example, FIG. 3 illustrates a circuit diagram of an oscillator 200 similar to that shown in FIG. 2, but implemented with nanoscale structures, according to one embodiment of the present disclosure. In one aspect of this embodiment, a closed loop nanoscale structure 500, such as a single looped nanowire or carbon nanotube, or an assembly of nanowires or carbon nanotubes forming a closed loop, serves as a high-frequency current path in the oscillator 200. The distributed quantum inductance and combined distributed electrostatic and quantum capacitance of the closed loop nanoscale structure 500 provide the energy storage mechanisms required for oscillation. The closed loop configuration of the nanoscale structure 500 avoids the need for metal-nanostructure junctions that would otherwise introduce undesirable resistance in the high-frequency current path.

According to one embodiment, the closed loop nanoscale structure 500 may be implemented as a single-walled carbon nanotube (SWNT) ring (see H. R. Shea, R. Martel and Ph. Avouris, “Electrical Transport in Rings of Single-Wall Nanotubes: One-Dimensional Localization,” Phys. Rev. Lett., Vol. 84, No. 19, May 2000, pp. 4441-4444; and R. Martel, H. R. Shea and Ph. Avouris, “Ring Formation in Single-Wall Carbon Nanotubes,” Journal of Physical Chemistry B, Vol. 102, No. 36, September 1999, pp. 7551-7556, each of which references hereby is incorporated herein by reference. Hereafter, these references are referred to collectively as “the IBM references”). Such SWNT rings have been fabricated having radii r on the order of 300-700 nanometers and tube widths on the order of 1 to 30 nanometers. Using 2πr as an approximation for ring circumference yields a path length l traversing around the ring on the order of approximately two to five micrometers.

A reasonable estimate for the oscillation frequency f of the oscillator 200 of FIG. 3 is given by:

$$f \approx \frac{{v}_{f}}{λ} , \qquad ( 2 )$$

where ν_{f} is the Fermi velocity of electrons in carbon nanotubes (8×10⁵ meters/sec), and λ is the wavelength of oscillation. In one exemplary implementation, the path length l of the closed loop nanoscale structure 500 is assumed to support a high-frequency current standing wave in the oscillator. More specifically, to provide an illustrative example, a closed loop structure having a path length l is considered wherein the path length l is one-half of a wavelength of oscillation (l=λ/2) so as to support a standing wave. Accordingly, assuming a path length of approximately two to five micrometers for the ring structures discussed above, from Eq. (2) such SWNT ring structures would support oscillating frequencies on the order of 80 to 200 GHz. It should be appreciated that the present disclosure is not limited to the foregoing example, however, as different path lengths l for the closed loop nanoscale structure 500 are possible, and may support standing waves based on integer multiples of the half-wavelength of oscillation (e.g., l=n(λ/2), where n is an integer). Also, as discussed further below, nanostructures other than the SWNT rings discussed in the IBM references may be employed to implement the closed loop nanoscale structure 500 according to other embodiments, in which a number of different possible path lengths l may be realized.

Like the oscillator shown in FIG. 2, the oscillator 200 of FIG. 3 includes a pair of cross-coupled FETs 214A and 214B that are implemented along a portion of the closed loop nanoscale structure 500. FETs have been fabricated using both semiconductor nanowires and carbon nanotubes (see R. Martel, T. Schmidt, H. R. Shea, T. Hertel, Ph. Avouris, “Single- and multi-wall carbon nanotube field-effect transistors,” Appl. Phys. Lett., vol. 73, pp 2447-2449, 1998; X. Duan, Y, Huang, Y. Cui, J. Wang, C. M. Leiber, “Indium phosphide nanowires as building blocks for nanoscale electronic and optoelectronic devices,” Nature, vol. 409, pp 66-69, 2001; Y. Cui, C. M. Leiber, “Functional nanoscale electronic devices assembled using silicon nanowire building blocks,” Science, vol. 291, pp 851-853, 2001, and A. Javey et al., “Carbon Nanotube Field-Effect Transistors with Integrated Ohmic Contacts and High-K Gate Dielectrics,” Nanoletters, Vol. 4, No. 3, 2004, pp. 447-450, each of which references hereby is incorporated herein by reference).

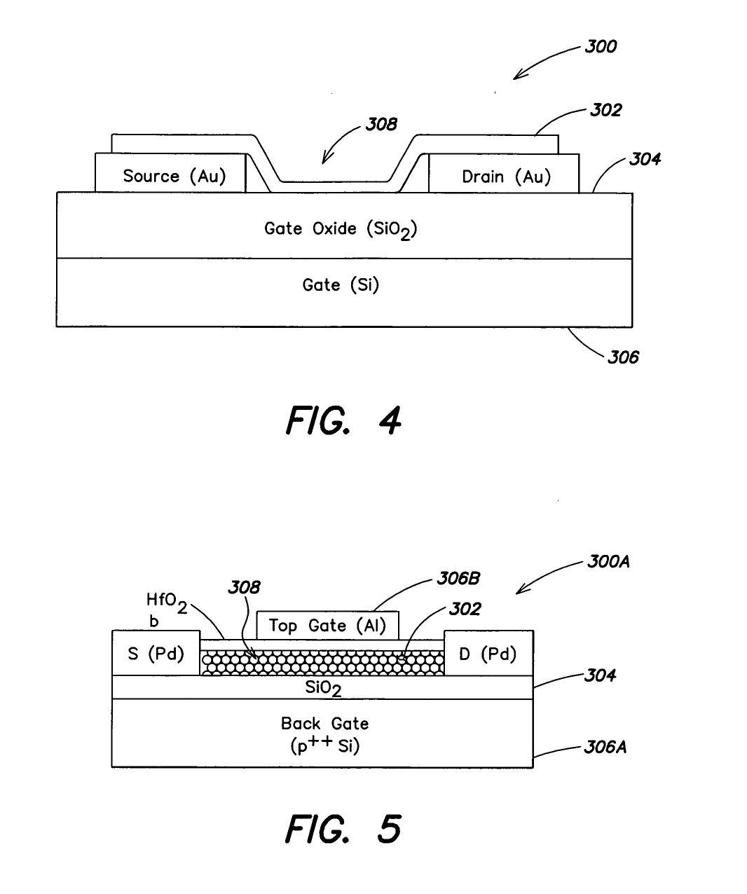

FIGS. 4 and 5 show various examples of a carbon nanotube FET 300 that may serve as a building block for the FETs 214A and 214B of the oscillator 200 shown in FIG. 3. In FIG. 4, a gate 306 of the FET 300 is formed by silicon (Si), which in some implementations may constitute a conventional substrate. A layer of silicon oxide 304 (SiO₂) is deposited over the silicon gate to provide a gate oxide for the FET, and two gold electrodes are deposited on the gate oxide 304 to serve as respective source and drain connections to a nanotube 302, which is positioned above the gate oxide and gold electrodes. Measured electrical characteristics of the nanotube FET shown in FIG. 4 find that an amount of current flowing through a channel 308 formed by the nanotube 302 in the area of the gate oxide can be changed by a factor of 100,000 by changing an applied voltage to the gate 306. The FET 300A of FIG. 5 includes a top gate electrode 306B (aluminum) as well as a “back” gate 306A constituted by doped silicon.

Based on the general structure of the carbon nanotube FETs shown in FIGS. 4 and 5, similar FETs may be implemented for the FETs 212A and 214B in the oscillator circuit 200 of FIG. 3. More specifically, since the source and drain contacts shown in FIGS. 4 and 5 are not required given the closed loop nanoscale structure 500 shown in FIG. 3, in one embodiment the FETs 212A and 214B may be implemented by covering respective small areas of the nanoscale structure 500 (corresponding to respective channels of the FETs) with a gate oxide, over which may be deposited respective metal gate contacts 214A and 214B.

In the oscillator 200 of FIG. 3, a DC bias needs to be provided for the FETs 212A and 214B, as well as interconnections to provide for cross coupling of the FET gate contacts 214A and 214B to alternate drains of the FETs. To this end, according to another aspect of the embodiment shown in FIG. 3, a number of nanostructure branches 150A, 150B, 150C and 150D are implemented along the closed loop nanoscale structure 500 so that connections involving DC bias and transistor cross-coupling do not introduce significant resistance in the high-frequency current path due to metal contacts used to couple to the nanoscale structure. The growth of branched nanostructures is discussed in detail, for example, in D. Wang, F. Qian, C. Yang, Z. Zhong and C. Lieber, “Rational Growth of Branched and Hyperbranched Nanowire Structures,” Nanoletters, Vol. 4, No. 5, March 2004, pp. 871-874, hereby incorporated herein by reference, and hereafter referred to as “the Wang reference.”

In another exemplary embodiment, as an alternative to the carbon nanotube rings discussed in the IBM references indicated above, the closed loop nanoscale structure 500 itself may be implemented as an assembly of branched nanostructures (e.g., as discussed in the Wang reference) that are coupled together to form a closed loop path for the high-frequency current in the oscillator 200. In one aspect of this alternative embodiment, an overall path length for the high frequency current may be similar to or appreciably different from the circumference of the rings discussed above, based on various possible configuration for an assembly of branched nanostructures. The ability to provide different path lengths for the high frequency current in an assembly of branched nanostructures results in a range of possible oscillating frequencies according to Eq. (2) that may be different than that for oscillators based on the dimensions of the specific ring structures discussed above (in connection with the IBM references).

While the nanostructure branches 150A, 150B, 150C and 150D shown in FIG. 3 alleviate metal-nanostructure junctions in the high-frequency current path, in one aspect of the oscillator 200 a number of metal-nanostructure junctions still may be required in some implementations. For example, as illustrated in FIG. 3, metal-nanostructure junctions 120A and 120B are required to couple the closed loop structure 500 to the DC bias voltage 114 and the current source 116, respectively (metal conductors are indicated in FIG. 3 using thicker lines than those used to indicate nanostructures). Additionally, metal-nanostructure junctions 120C and 120D are required to couple the respective metal gates 214B and 214A of the FETs to the closed loop structure 500 (the high-frequency signal representing an output of the oscillator may be taken from the metal gates 214B and 214A). Again, however, any contact resistance introduced by the metal-nanostructure junctions 120A, 120B, 120C and 120D would not be in the high-frequency current path formed by the closed loop structure 500.

Although various examples provided above involve the quantum inductance associated with one-dimensional nanoscale structures such as nanowires and carbon nanotubes, it should be appreciated that applicability of the concepts disclosed herein is not limited in this respect. For example, other types of current paths that exhibit a quantum inductance, for example a lithographically-defined nanometer-scale current path formed in a 2-dimensional electron gas (2DEG) in a semiconductor heterostructure or graphene, are contemplated by the present disclosure as finding applicability to high-frequency integrated circuit realization. Such quantum wires may be fabricated by etching, patterned gates, or ion-implantation using a 2DEG (e.g., see T. H. Oosterkamp et al., “Microwave Spectroscopy of a Quantum-dot Molecule,” Letters to Nature, Vol. 395, October 1998, pp. 873-876, hereby incorporated herein by reference).

Having thus described illustrative embodiments, it is to be appreciated that various alterations, modifications, and improvements will readily occur to those skilled in the art. Such alterations, modifications, and improvements are intended to be part of this disclosure, and are intended to be within the spirit and scope of this disclosure. While some examples presented herein involve specific combinations of functions or structural elements, it should be understood that those functions and elements may be combined in other ways according to the present disclosure to accomplish the same or different objectives. In particular, acts, elements, and features discussed in connection with one embodiment are not intended to be excluded from similar or other roles in other embodiments. Accordingly, the foregoing description and attached drawings are by way of example only, and are not intended to be limiting.

What is claimed is:

1. An integrated circuit, comprising:
a closed loop path formed by at least one nanoscale structure; and
a pair of cross-coupled field effect transistors (FETs) implemented along the closed loop path, wherein two portions of the at least one nanoscale structure form respective channels of the cross-coupled FETs.

2. The circuit of claim 1, wherein the closed loop path includes a single nanoscale structure forming a ring.

3. The circuit of claim 1, wherein the closed loop path includes multiple nanoscale structures coupled together.

4. The circuit of claim 1, wherein the closed loop path does not include any junctions with non-nanoscale structures.

5. The circuit of claim 1, wherein the at least one nanoscale structure includes at least one carbon nanotube.

6. The circuit of claim 1, wherein the at least one nanoscale structure includes at least one nanowire that does not contain carbon.

7. The circuit of claim 1, wherein the closed loop path includes a plurality of nanostructure branches to facilitate a coupling of at least one signal to or from the closed loop path.

8. The circuit of claim 7, wherein:
a first FET of the cross-coupled FETs includes a first non-nanostructure conducting gate contact coupled to a first nanostructure branch of the plurality of nanostructure branches; and
a second FET of the cross-coupled FETs includes a second non-nanostructure conducting gate contact coupled to a second nanostructure branch of the plurality of nanostructure branches.

9. The circuit of claim 8, further comprising at least one DC current source coupled to a third nanostructure branch of the plurality of nanostructure branches, and a non-nanostructure conducting contact coupled to a fourth nanostructure branch of the plurality of nanostructure branches, wherein the fourth nanostructure branch facilitates a coupling of a DC bias voltage to the closed loop path.

10. The circuit of claim 1, wherein the at least one nanoscale structure forming the closed loop path has a distributed quantum inductance, a distributed quantum capacitance, and a distributed electrostatic capacitance, and wherein the circuit is configured as an oscillator to generate a high-frequency wave on the closed loop path based at least in part on the distributed quantum inductance, the distributed quantum capacitance, and the distributed electrostatic capacitance of the at least one nanoscale structure.

11. A method, comprising:
(A) generating a standing wave on a closed loop path formed by at least one nanoscale structure.

12. The method of claim 11, wherein the closed loop path includes a single nanoscale structure forming a ring.

13. The method of claim 11, wherein the closed loop path includes multiple nanoscale structures coupled together.

14. The method of claim 11, wherein the closed loop path does not include any junctions with non-nanoscale structures.

15. The method of claim 11, wherein the at least one nanoscale structure includes at least one carbon nanotube.

16. The method of claim 11, wherein the at least one nanoscale structure includes at least one nanowire that does not contain carbon.

17. The method of claim 11, wherein the closed loop path includes at least one nanostructure branch to facilitate a coupling of a signal to or from the closed loop path.

18. The method of claim 11, wherein the closed loop path includes at least one field-effect transistor (FET) implemented using the at least one nanoscale structure.

19. The method of claim 18, wherein the at least one FET includes two FETs.

20. The method of claim 19, wherein the at least one nanoscale structure has a distributed quantum inductance, a distributed quantum capacitance, and a distributed electrostatic capacitance, and wherein the act (A) includes an act of:
applying a DC bias to the two FETs so as to generate the standing wave based at least in part on the distributed quantum inductance, the distributed quantum capacitance, and the distributed electrostatic capacitance of the at least one nanoscale structure.

21. An apparatus, comprising:
a high-frequency current path formed by at least one nanoscale structure; and
at least one non-nanoscale conducting structure coupled to the at least one nanoscale structure, wherein the high-frequency current path includes only the at least one nanoscale structure.

22. The apparatus of claim 21, wherein the high-frequency current path includes a closed loop path formed by the at least one nanoscale structure.

23. The apparatus of claim 22, wherein the at least one nanoscale structure includes a single nanoscale structure forming a ring.

24. The apparatus of claim 22, wherein the at least one nanoscale structure includes multiple nanoscale structures coupled together.

25. The apparatus of claim 21, wherein the at least one nanoscale structure includes at least one carbon nanotube.

26. The apparatus of claim 21, wherein the at least one nanoscale structure includes at least one nanowire that does not contain carbon.

27. The apparatus of claim 21, wherein the high-frequency current path includes at least one nanostructure branch to facilitate a coupling of a signal to or from the high-frequency current path.

28. The apparatus of claim 21, wherein the high-frequency current path includes at least one field-effect transistor (FET) implemented using the at least one nanoscale structure.

29. The apparatus of claim 28, wherein the at least one FET includes two FETs.

30. The apparatus of claim 29, wherein the at least one nanoscale structure forming the high-frequency current path has a distributed quantum inductance, a distributed quantum capacitance, and a distributed electrostatic capacitance, and wherein the apparatus further comprises:
at least one component configured to apply a DC bias to the two FETs so as to generate a high-frequency wave on the high-frequency current path based at least in part on the distributed quantum inductance, the distributed quantum capacitance, and the distributed electrostatic capacitance of the at least one nanoscale structure.
